(19) United States
(12) Patent Application Publication
(10) Pub. No.: US 2019/0245004 A1
(43) Pub. Date: Aug. 8, 2019

(54) LIGHT EMITTING DEVICE

(71) Applicant: MIKRO MESA TECHNOLOGY CO., LTD., Apia (WS)

(72) Inventors: Li-Yi CHEN, Tainan City (TW); Hsin-Wei LEE, Tainan City (TW)

(21) Appl. No.: 15/892,352

(22) Filed: Feb. 8, 2018

(51) Int. Cl. H01L 27/15

(52) U.S. Cl. CPC H01L 27/15; H01L 33/24

(57) ABSTRACT

A light-emitting device including a first type semiconductor layer, a second type semiconductor layer, a plurality of first electrodes, and a second electrode is provided. The first type semiconductor layer includes a plurality of low resistance portions and a high resistance portion. The low resistance portions are isolated from each other by the high resistance portion, and a resistivity of the first type semiconductor layer increases from the low resistance portions toward the high resistance portion. The second type semiconductor layer is joined with the first type semiconductor layer. The plurality of first electrodes are electrically connected to the low resistance portions, and each of the first electrodes is electrically isolated from one another. The second electrode is electrically connected to the second type semiconductor layer.

### BACKGROUND

### Field of Invention

The present disclosure relates to a light emitting device.

### Description of Related Art

The statements in this section merely provide background information related to the present disclosure and do not necessarily constitute prior art.

In recent years, micro light emitting devices have become popular in general and commercial lighting applications. As light sources, LEDs have many advantages including low energy consumption, long lifetime, small size, and fast switching, and hence conventional lighting, such as incandescent lighting, is gradually replaced by LED lights. These properties are promising for applications on displays.

Since the displays are used under a variety of environmental conditions, controlling precisely the brightness of LEDs becomes important. However, the inventor recognizes that, current density is approximately an exponential function of voltage near the threshold for an LED, so that a small voltage change will result in large variation in current density. Thus, controlling currents flowing through a micro device is an important technical issue in nowadays applications.

### SUMMARY

According to some embodiments of the present disclosure, a light-emitting device including a first type semiconductor layer, a second type semiconductor layer, a plurality of first electrodes, and a second electrode is provided. The first type semiconductor layer includes a plurality of low resistance portions and a high resistance portion. The low resistance portions are isolated from each other by the high resistance portion, and a resistivity of the first type semiconductor layer increases from the low resistance portions toward the high resistance portion. The second type semiconductor layer is joined with the first type semiconductor layer. The plurality of first electrodes are electrically connected to the low resistance portions, and each of the first electrodes is electrically isolated from one another. The second electrode is electrically connected to the second type semiconductor layer.

It is to be understood that both the foregoing general description and the following detailed description are by examples, and are intended to provide further explanation of the invention as claimed.

### BRIEF DESCRIPTION OF THE DRAWINGS

The invention can be more fully understood by reading the following detailed description of the embodiment, with reference made to the accompanying drawings as follows:

FIG. 1A is a schematic top view of a light emitting device according to some embodiments of the present disclosure;

FIG. 1B is a schematic cross-sectional view of the light emitting device 100 according to some embodiments of the present disclosure;

FIG. 1C is a schematic light emitting device circuit;

FIG. 2A is a schematic top view of a light emitting device according to some embodiments of the present disclosure;

FIG. 2B is a is a schematic light emitting device circuit;

FIG. 3A is a schematic top view of a light emitting device according to some embodiments of the present disclosure;

FIG. 3B is a schematic top view of a light emitting device according to some embodiments of the present disclosure;

FIG. 4 is a schematic distribution of resistance of the first type semiconductor layer according to some embodiments of the present disclosure;

FIG. 5 is a schematic cross-sectional view of a light emitting device according to some embodiments of the present disclosure; and

FIG. 6 is a schematic step method 600 for operating a light-emitting device.

### DETAILED DESCRIPTION

Reference will now be made in detail to the present embodiments of the invention, examples of which are illustrated in the accompanying drawings. Wherever possible, the same reference numbers are used in the drawings and the description to refer to the same or like parts.

In various embodiments, description is made with reference to figures. However, certain embodiments may be practiced without one or more of these specific details, or in combination with other known methods and configurations. In the following description, numerous specific details are set forth, such as specific configurations, dimensions and processes, etc., in order to provide a thorough understanding of the present invention. In other instances, well-known semiconductor processes and manufacturing techniques have not been described in particular detail in order to not unnecessarily obscure the present invention. Reference throughout this specification to “one embodiment,” “an embodiment” or the like means that a particular feature, structure, configuration, or characteristic described in connection with the embodiment is included in at least one embodiment of the invention. Thus, the appearances of the phrase “in one embodiment,” “in an embodiment” or the like in various places throughout this specification are not necessarily referring to the same embodiment of the invention. Furthermore, the particular features, structures, configurations, or characteristics may be combined in any suitable manner in one or more embodiments.

The terms “over,” “to,” “between” and “on” as used herein may refer to a relative position of one layer with respect to other layers. One layer “over” or “on” another layer or bonded “to” another layer may be directly in contact with the other layer or may have one or more intervening layers. One layer “between” layers may be directly in contact with the layers or may have one or more intervening layers.

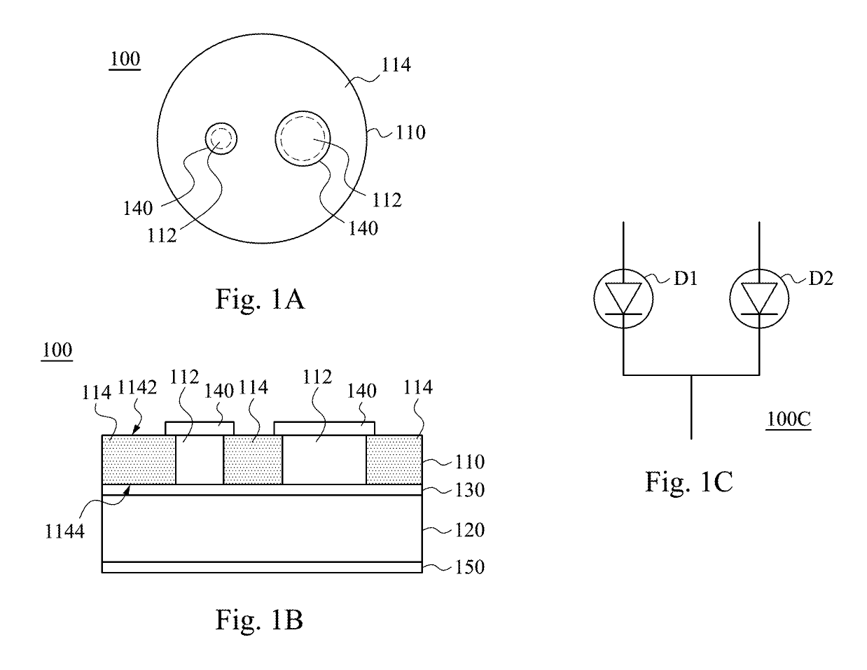

Reference is made to FIGS. 1A to 1C. FIG. 1A is a schematic top view of a light emitting device 100 according to some embodiments of the present disclosure. FIG. 1B is a schematic cross-sectional view of the light emitting device 100 according to some embodiments of the present disclosure. FIG. 1C is a schematic light emitting device circuit 100C.

According to some embodiments of the present disclosure, a light emitting device 100 including a first type semiconductor layer 110, a second type semiconductor layer 120, a plurality of first electrodes 140, and a second electrode 150 is provided. In some embodiments, the light emitting device 100 may be a micro light emitting diode (micro-LED). A size of the micro-LED may be less than 100 μm, or less than 50 μm. The first type semiconductor layer 110 includes a plurality of low resistance portions 112 and a high resistance portion 114. Specifically, the low resistance portions 112 are isolated from each other by the high resistance portion 114. A plurality of first electrodes 140 are electrically connected to the low resistance portions 112 respectively, wherein each of the first electrodes 140 is electrically isolated from one another. In addition, a second electrode 150 is electrically connected to the second type semiconductor layer 120. Thus, the configuration of the light emitting device 100 may be simplified to a circuit diagram as illustrated in FIG. 1C, i.e. diodes D1, D2 which can be individually controlled and share a common end.

The second type semiconductor layer 120 is joined with the first type semiconductor layer 110. In some embodiments, an active layer 130 is connected between the first type semiconductor 110 layer and the second type semiconductor layer 120, and a resistivity of the first type semiconductor layer 110 increases from the low resistance portions 112 toward the high resistance portion 114. Besides, the resistivity of the high resistance portion 114 near a side 1142 thereof adjacent to the first electrodes 140 may be greater than the resistivity of the high resistance portion 114 near a side 1144 thereof adjacent to the active layer 130. Specifically, changes in resistivity of the high resistance portion 114 may be caused by diffusion or doping. The diffusion may be performed by depositing a metal on the high resistance portion 114 and optionally heating. The metal may be Ti or Si, but should not be limited thereto. Doping may be performed from one side of the high resistance portion 114, such as doping from the side 1142, but should not be limited thereof. In such a case, the resistivity near the side 1142 reveals higher than that near the side 1144, as described above.

In some other embodiments, the resistivity of the high resistance portion 114 near a side 1142 thereof adjacent to the first electrodes 140 may also be substantially the same as the resistivity of the high resistance portion 114 near a side thereof adjacent to the active layer 130.

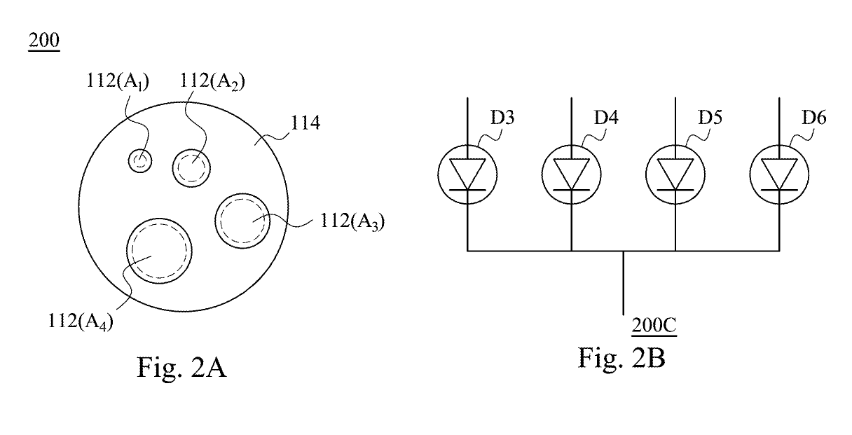

The following paragraph explains the distributions, sizes, and geometries of the plurality of the low resistance portions 112. Reference is made to FIGS. 2A and 2B. FIG. 2A is a schematic top view of a light emitting device 200 according to some embodiments of the present disclosure. FIG. 2B is a schematic light emitting device circuit 200C. In some embodiments, the low resistance portions 112 have cross sectional areas of A₁ to Aₙ respectively, wherein n is a total number of the low resistance portions, and An is larger than or equal to Aₙ₋₁. Taking four low resistance portions 112 as an example, the low resistance portions 112 have cross-sectional areas denoted by A₁, A₂, A₃, and A₄, respectively. As shown in FIG. 2A, in some embodiments, A₁<A₂<A₃<A₄. This configuration may be represented by FIG. 2B, a schematic circuit diagram with each low resistance portions 112 representing a diode D3, D4, D5, D6 respectively, and all four diodes D3, D4, D5, D6 share a common end. The common end can be performed by the second electrode 150. Given this scenario, currents passing through the four different cross-sectional areas A₁ to A₄ may have different values even under the same applied voltage or current density. As a result, a light emitting device 200 acts as multiple light emitting diodes and enables digital controlling on currents, and so does brightness, since brightness is proportional to the sum of currents passing through the cross-sectional areas A₁, A₂, A₃, and A₄. The reason for “digital” is, for example, when the same voltage or current density is applied, the low resistance portions A₁, A₂, A₃, and A₄ may be chosen individually, such that the total current passing through the light emitting device 200 may be a value of the applied current density times a cross-sectional area A₁, A₂, A₃, A₄, (A₁+A₂), (A₁+A₃), (A₁+A₄), (A₂+A₃), (A₂+A₄), (A₃+A₄), (A₁+A₂+A₃), (A₁+A₂+A₄), (A₁+A₃+A₄), (A₂+A₃+A₄), or (A₁+A₂+A₃+A₄). Therefore, there are total 15 values of total current selectable for a single applied voltage or current density in the embodiments illustrated in FIG. 2A.

More specifically, for the embodiments mentioned above, a current density may be operated in the low resistance portions 112 within a range between Jₐ and J_{b}, wherein Jₐ and J_{b} can be artificially chosen, and J_{b} is greater than Jₐ. Therefore, a current value of the light emitting device is within a range of A₁*Jₐ to (A₁+A₂+ . . . +Aₙ)*J_{b}. The value A₁*Jₐ is performed by operating a current density Ja only through the low resistance portion 112 with cross-sectional area A₁, and the value (A₁+A₂+ . . . +Aₙ)*J_{b} is performed by operating a current density Jb through the low resistance portions 112 with cross-sectional areas A₁, A₂, . . . , Aₙ. Besides, any combination of cross-sectional areas selected from A₁, A₂, A₃, . . . , Aₙ and current density values selected between Jₐ and J_{b} may be chosen to be operated on the light emitting device 200. In some embodiments, a current density between Jₐ and J_{b} or off current may also be applied to each of the cross-sectional areas Aₖ (k is one of integers from 1 to n), that is, each cross-sectional areas Aₖ has its own degree of freedom in choosing applied current density or voltage.

Embodiments as illustrated in FIGS. 1A to 2B can reach better controls on brightness of a single light emitting device 100, 200 with one semiconductor layer, such as a p-type semiconductor layer, being divided into low resistance portions and high resistance portions. At the same time, the other semiconductor layer, such as a n-type semiconductor layer, is common. This configuration has advantages of reducing costs.

Considering the topology of the first semiconductor layer 110, in some embodiments, at least one of the low resistance portions 112 is enclosed by the high resistance portion 114, such as those shown in FIGS. 1A and 2A. In FIG. 1A, both two low resistance portions 112 are enclosed by the high resistance portion 114. In FIG. 2A, all four low resistance portions 112 with cross-sectional areas A₁, A₂, A₃, and A₄ are enclosed by the high resistance portion 114.

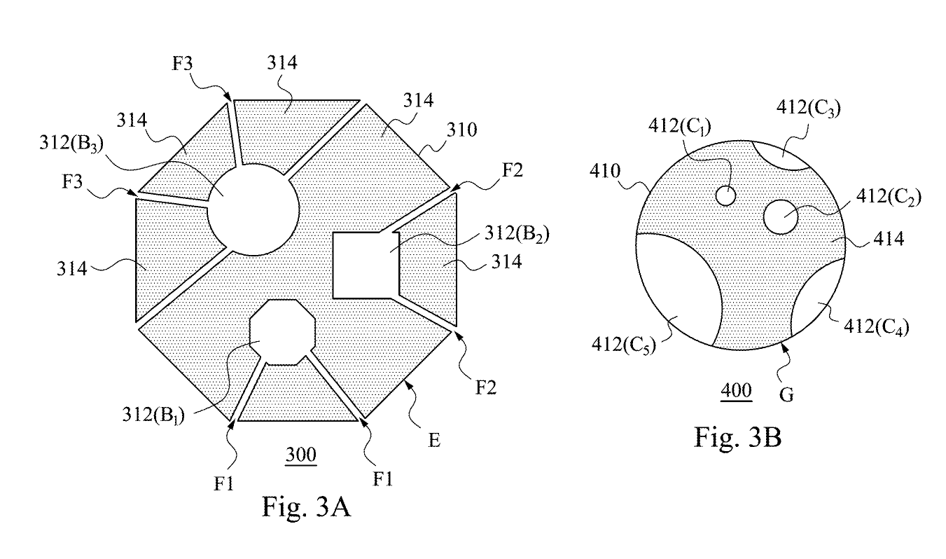

In some other embodiments, at least one of the low resistance portions 112 is extended to an edge of the first type semiconductor layer. Reference is made to FIGS. 3A and 3B. FIG. 3A is a schematic top view of a light emitting device 300 according to some embodiments of the present disclosure. FIG. 3B is a schematic top view of a light emitting device 400 according to some embodiments of the present disclosure. In FIG. 3A, an octagonal low resistance portion 312 with cross-sectional area B₁ has two extension regions F1 which extend to the edge E of the first type semiconductor layer 310. A square low resistance portion 312 with cross-sectional area B₂ has two extension regions F2 which extend to the edge E of the first type semiconductor layer 310. A circular low resistance portion 312 with cross-sectional area B₃ has four extension regions F3 which extend to the edge E of the first type semiconductor layer 310. In these configurations, although the low resistance portions 312 are electrically isolated from one another by one of the high resistance portions 314, the low resistance portions 312 are not enclosed by the high resistance portions 314. In FIG. 3B, there are low resistance portions 412 having cross-sectional areas C₁ and C₂ which are isolated and enclosed by the high resistance portion 414. In addition, there are also low resistance portions 412 having cross-sectional areas C₃, C₄ and C₅ which are isolated by, but not enclosed by the high resistance portion 414. Besides, C₃, C₄ and C₅ also extend to the edge G of the first type semiconductor layer 410.

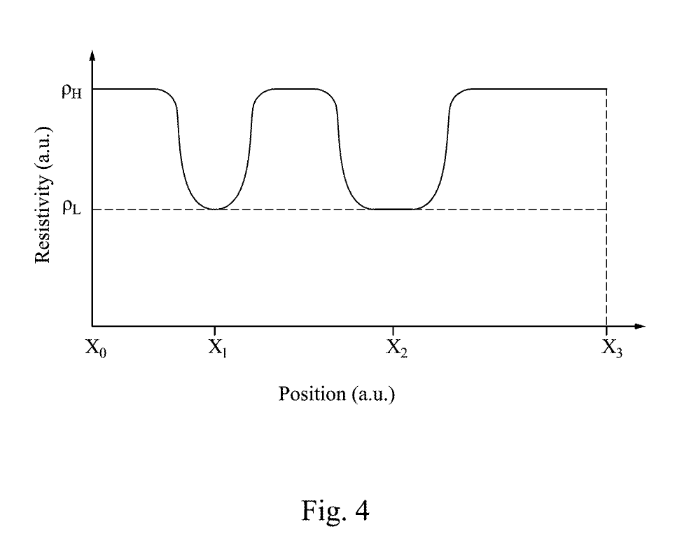

Reference is made to FIG. 4. Considering distributions of resistivity, in some embodiments as can be illustrated in FIGS. 1A to 3B, each of the low resistance portions 112,312 may have at least one location with a local minimum resistivity. FIG. 4 is a schematic distribution of resistance of the first type semiconductor layer 110 according to some embodiments of the present disclosure. X₀, X₁, X₂, and X₃ are positions of the first type semiconductor layer 110 along the side 1142 in FIG. 1B, wherein X₁ and X₂ are within the low resistance regions 112, X₀ and X₃ are within the high resistance region 114. ρ_{H} represents the highest resistivity along the side 1142, and ρ_{L} represents the local minimum resistivity along the side 1142. Although the two local minimum resistivities reveal the same in FIG. 4, it should not be limited thereto. Different local minimum resistivities may also exist in other embodiments. As depicted, the change of resistivity near the interface of the low resistance portions 112 and the high resistance portion 114 are smooth and continuous, such as in exponential way. The smooth and continuous variation may be caused by, for example, diffusion or doping, but should not be limited herein. Details of diffusion and doping have been mentioned above and will not be repeated here. Furthermore, although in FIG. 4 only low resistance portions 112 corresponding to FIGS. 1A and 1B is illustrated, it should not be limited thereto. Low resistance portions 312, 412 as illustrated by FIGS. 3A and 3B may also have similar resistivity distributions as that in FIG. 4.

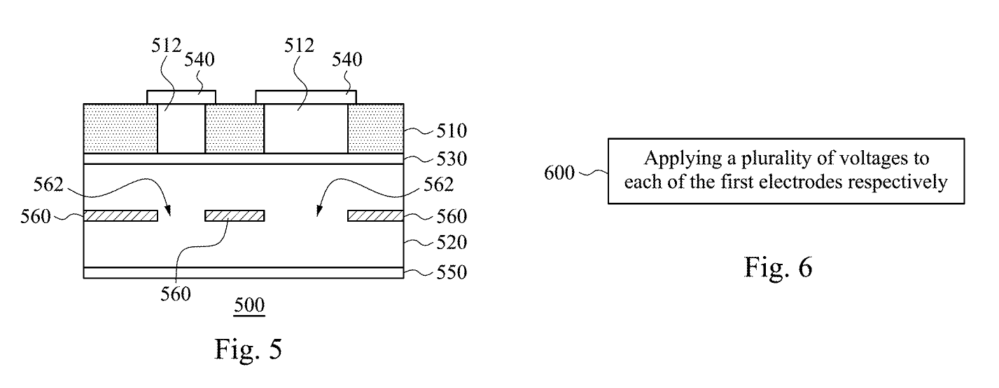

Reference is made to FIG. 5. FIG. 5 is a schematic cross-sectional view of a light emitting device 500 according to some embodiments of the present disclosure. The difference between embodiments illustrated in FIG. 5 and embodiments illustrated in FIG. 1B is that, embodiments of FIG. 5 further comprise a current control layer 560 which may be selectively present in the light emitting device 500 between the first electrodes 540 and the second electrode 550. The current control layer 560 has a plurality of openings 562. Specifically, the current control layer 560 may be joined with the first type semiconductor layer 510, or the second type semiconductor layer 520. There may also be a plurality of current control layers 560 present within the first type semiconductor layer 510, the second type semiconductor layer 520, or the combinations thereof. The plurality of current control layers 560 may also present on the interfaces of the first type semiconductor layer 510, the second type semiconductor layer 520, or combinations thereof. The interfaces may include an interface between the first type semiconductor layer 510 and the first electrodes 540, an interface between the first type semiconductor layer 510 and the active layer 530, an interface between the active layer 530 and the second type semiconductor layer 520, and an interface between the second type semiconductor layer 520 and the second electrode 550.

For making confined currents flow through the low resistance portions 512 of the light emitting device 500, a plurality of vertical projections of a plurality of the openings 562 of each of the current control layers 560 on the first type semiconductor layer 510 at least partially overlap with a plurality of vertical projections of the low resistance portions 512 on the first type semiconductor layer 510. Specifically, in some embodiments, vertical projections of the openings 562 of each of the current control layers 560 on the first type semiconductor layer 510 at least partially overlap with vertical projections of the low resistance portions 512 on the first type semiconductor layer 510 respectively. For example, if there is only one current control layer 560 and two low resistance portions 512 present, the current control layer 560 would have two openings 562. Vertical projections of the two openings 562 on the first type semiconductor layer 510 at least partially overlap with and correspond respectively to vertical projections of the low resistance portions 512 on the first type semiconductor layer 510. In another example, if there are two current control layers 560 and two low resistance portions 512, each of the current control layers 560 has two openings 562 and there are totally four openings 562. Vertical projections of two of the openings 562 from the two current control layers 560 on the first type semiconductor layer 510 at least partially overlap with and correspond respectively to vertical projections of one of the low resistance portions 512 on the first type semiconductor layer 510, and vertical projections of the other two openings 562 from the two current control layers 560 on the first type semiconductor layer 510 at least partially overlap with and correspond respectively to vertical projections of the other low resistance portion 512 on the first type semiconductor layer 510.

Reference is made to FIG. 6. FIG. 6 is a schematic step method 600 for operating a light-emitting device. The main step of the method 600 is to apply a plurality of voltages to the first electrodes respectively, such that each of the first electrodes may provide a voltage selected from a range between V1 and V2, wherein V1 and V2 can be chosen artificially. In some embodiments, the voltages applied to two of the first electrodes have different values. For example, if there are ten first electrodes, two of the first electrodes among these ten first electrodes may be applied with different voltages. In some other embodiments, the voltages applied to all of the first electrodes have the same value. The embodiments mentioned above enable digital controls on brightness within a single light emitting device. As a result, a single light emitting device acts as multiple light emitting diodes where the brightness of which can be fine-tuned.

In summary, a plurality of low resistance portions of a first type semiconductor layer with a plurality of isolated first electrodes, a common second type semiconductor layer and a common second electrode enables a digital control on a single light emitting device. The single light emitting device may act as multiple light emitting diodes. This configuration may be applied to, for example, a micro-LED, such that it is easier to control the brightness of one micro-LED.

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. A light-emitting device, comprising:
a first type semiconductor layer comprising:
a plurality of low resistance portions;
a high resistance portion, wherein the low resistance portions are isolated from each other by the high resistance portion, and a resistivity of the first type semiconductor layer increases from the low resistance portions toward the high resistance portion;
a second type semiconductor layer joined with the first type semiconductor layer;
a plurality of first electrodes electrically connected to the low resistance portions, wherein each of the first electrodes is electrically isolated from one another; and
a second electrode electrically connected to the second type semiconductor layer.

2. The light-emitting device of claim 1, further comprising an active layer connected between the first type semiconductor layer and the second type semiconductor layer.

3. The light-emitting device of claim 2, wherein the resistivity of the high resistance portion near a side thereof adjacent to the first electrodes is greater than the resistivity of the high resistance portion near a side thereof adjacent to the active layer.

4. The light-emitting device of claim 2, wherein the resistivity of the high resistance portion near a side thereof adjacent to the first electrodes is substantially the same as the resistivity of the high resistance portion near a side thereof adjacent to the active layer.

5. The light-emitting device of claim 1, wherein the low resistance portions have cross sectional areas of A₁ to Aₙ respectively, n is a total number of the low resistance portions, and Aₙ is larger than or equal to Aₙ₋₁.

6. The light-emitting device of claim 1, wherein at least one of the low resistance portions is enclosed by the high resistance portion.

7. The light-emitting device of claim 1, wherein at least one of the low resistance portions is extended to an edge of the first type semiconductor layer.

8. The light-emitting device of claim 1, further comprising a current control layer present between the first electrodes and the second electrode, wherein the current control layer has a plurality of openings.

9. The light-emitting device of claim 8, wherein a plurality of vertical projections of the openings on the first type semiconductor layer at least partially overlap with a plurality of vertical projections of the low resistance portions on the first type semiconductor layer.

10. The light-emitting device of claim 1, wherein each of the low resistance portions has at least one location with a local minimum resistivity.

11. A method for operating a light-emitting device of claim 1, comprising:
applying a plurality of voltages to the first electrodes respectively.

12. The method of claim 11, wherein the voltages applied to two of the first electrodes have different values.

13. The method of claim 11, wherein the voltages applied to all of the first electrodes have the same value.
